(19) United States
(12) Patent Application Publication
(10) Pub. No.: US 2015/0370161 A1
(43) Pub. Date: Dec. 24, 2015

(54) DEVICE AND METHOD FOR NANO-IMPRINT LITHOGRAPHY

(71) Applicant: SHANGHAI INTEGRATED CIRCUIT RESEARCH AND DEVELOPMENT DEVELOPMENT CENTER CO., LTD., Shanghai (CN)

(72) Inventor: Wei Yuan, Shanghai (CN)

(21) Appl. No.: 14/764,141

(22) PCT Filed: Aug. 11, 2014
(86) PCT No.: PCT/CN2014/084100

§ 371 Date: Jul. 28, 2015

(30) Foreign Application Priority Data
Sep. 26, 2013 (CN) 201310447608.4

(51) Int. Cl. G03F 7/00

(52) U.S. Cl. CPC G03F 7/0002

(57) ABSTRACT

A device for nano-imprint lithography to perform a lithography process to a substrate coated with an electron-sensitive resist. The device comprises a conductive imprint template and an electron source. The imprint template comprises a base portion and a pattern portion on the upper surface of the base portion. The surface of the pattern portion is disposed opposed to the surface of the resist. The pattern portion has a concave-convex pattern corresponding to a target pattern of the resist. The electron source provides electrons to the concave-convex pattern. When the concave-convex pattern contacts the resist, the electrons transfer from the concave-convex pattern to the resist to make the resist exposed. The device combines the advantages of the nano-imprint technology and the electron beam lithography, it has high process compatibility and improved alignment and overlay accuracy and is also conductive to defect control, which can obtain higher productivity and resolution.

### CROSS-REFERENCE TO RELATED APPLICATION

This application claims the priority benefit of International Patent Application Serial No. PCT/CN2014/084100, filed Aug. 11, 2014, which is related to and claims the priority benefit of China patent application serial no. 201310447608.4 filed Sep. 26, 2013. The entirety of each of the above-mentioned patent applications is hereby incorporated by reference herein and made a part of this specification.

### FIELD OF THE INVENTION

The present invention relates to the field of integrated circuit manufacturing and particularly to a device and method for the nano-imprint lithography.

### BACKGROUND OF THE INVENTION

With the continuing shrinking of semiconductor critical dimensions, lithography, which is a key process in integrated circuit manufacturing, is facing more and more challenges. One of the challenges is that, when the critical dimension and pitch of a pattern approaches the resolution of a lithography tool, image distortions are likely to occur on the wafer surface, as a result, the lithographic imaging quality is seriously deteriorated.

The semiconductor industry is focusing on the research and development of new lithography technology, and currently one of the mainstream direction towards the nano-imprint lithography.

The process of the nano-imprint lithography involves pressing a template having nano patterns against a resist on a wafer, and then performing treatments such as heating or UV curing to the resist to transfer the nano patterns to the resist. Since complicated optical systems or high-powered laser sources used in the conventional lithography process are not required, the nano-imprint lithography possesses the advantages of simple technology and low cost. Furthermore, high resolution can also be achieved by using a finished template.

However, problems still exist in the existing nano-imprint technology, such as the exhaust of waste gases generated during the thermoplastic imprinting process, the alignment and overlay issues resulting from expansions of the heated template and wafer, the damage to the template due to the pressure applied to the template after repeated imprinting processes, and the compatibility problems of the current thermoplastic imprinting process with the conventional semiconductor processes.

Therefore, the industry aims to optimize and modify the nano-imprint technology to solve the existing problems while retain its advantages.

### SUMMARY OF THE INVENTION

Accordingly, at least one object of this invention is to provide a new the nano-imprint technology which can improve the defects of waste gas production, template damage, low alignment and overlay accuracy, and poor process compatibility.

To achieve the above purpose, the present invention provides a device for the nano-imprint lithography to perform a lithography process to a substrate which is coated with an electron-sensitive resist. The device comprises a conductive imprint template and an electron source. The imprint template comprises a base portion and a pattern portion upright on the upper surface of the base portion. The surface of the pattern portion is disposed opposed to the surface of the resist. The pattern portion has a concave-convex pattern corresponding to a target pattern of the resist. The electron source provides electrons to the concave-convex pattern of the imprint template. When the concave-convex pattern of the template contacts the resist, the electrons transfer from the concave-convex pattern to the resist to make the resist exposed.

Preferably, the material of the base portion and that of the pattern portion are selected from at least one of metal, silicon and silicon germanium.

Preferably, the size of the base portion is equal to or smaller than that of the substrate.

Preferably, the base portion is rectangular or circular.

Preferably, the electron source is electron beam type or contact type.

Preferably, the electron source is a contact type electron source which covers the bottom surface of the base portion and has multiple evenly distributed electrical contacts on its surface to contact the bottom surface of the base portion.

Preferably, when the photoresist is positive type, the concave-convex pattern is the inverse of the target pattern of the resist; when the resist is negative type, the concave-convex pattern is the same as the target pattern of the resist.

To achieve the above purpose, the present invention also provides a method for the nano-imprint lithography, the method comprises the following steps:

step S1: manufacturing a conductive imprint template comprising a base portion and a pattern portion having a concave-convex pattern corresponding to a resist target pattern on the upper surface of the base portion;

step S2: coating electron-sensitive resist on the surface of a substrate;

step S3: performing alignment between the imprint template and the substrate by disposing the surface of the pattern portion opposite the surface of the resist;

step S4: making the surface of the concave-convex pattern in contact with the surface of the resist;

step S5: turning on an electron-beam type electron source or a contact type electron source to transfer electrons from the imprint template to regions where the resist and the concave-convex pattern contact with each other;

step S6: exposing the contact regions between the resist and the concave-convex pattern by the electrons to transfer the concave-convex pattern to the surface of the resist;

step S7: separating the imprint template from the resist;

step S8: performing baking and development to form the resist target pattern.

Preferably, hydrophilic pretreatment is performed to the surface of the pattern portion prior to the step S3.

Preferably, when the resist is positive type, the concave-convex pattern is the inverse of the resist target pattern; when the resist is negative type, the concave-convex pattern is the same as the resist target pattern.

The present invention combines the advantages of the nano-imprint technology and the electron beam lithography by transferring electrons from a conductive imprint template to an electron-sensitive resist to expose the surface of the resist so that the pattern of the imprint template can be transferred to the wafer to achieve the nano-imprint lithography.

According to the nano-imprint lithography of the present invention, contact electrical exposure is utilized instead of the conventional heating methods, thus the pattern can be transferred to the resist just by contacting the pattern of the template with the resist surface without any pressure to be applied, which significantly reduce defects and makes the template uneasy to be damaged. Furthermore, the problem of reduced alignment and overlay accuracy due to the expansion of heated template and wafer can also be avoided, thereby improving the resolution of imprint lithography without generating any waste gas on the wafer surface. In addition, the material of the resist used in the present invention and the subsequent steps of the lithography process such as development and resist stripping are the same as the existing steps, therefore, the nano-imprint lithography of the present invention has high compatibility and there is no need to develop any associated materials or equipment. Moreover, since the electrical exposure is instantaneous, higher productivity can be achieved while retaining high lithographic resolution.

### BRIEF DESCRIPTION OF THE DRAWINGS

FIG. 1 is a schematic diagram illustrating a device for nano-imprint lithography in an embodiment according to the present invention;

FIG. 2 is a schematic diagram illustrating a device for the nano-imprint lithography in another embodiment according to the present invention;

FIG. 3 is a flow chart illustrating a method for the nano-imprint lithography in an embodiment according to the present invention;

FIGS. 4-9 are sectional views illustrating the steps of the method for the nano-imprint lithography in the embodiment according to the present invention.

### DETAILED DESCRIPTION OF THE EMBODIMENTS

The features and advantages of the device and method for the nano-imprint lithography of the present invention will be described in detail as follows. The specific embodiments and the accompanying drawings discussed are merely illustrative of specific ways to make and use the invention, and do not limit the scope of the invention or the appended claims. It is noted that the accompanying drawings are simplified views with inaccurate size proportions, which merely used to help illustrating the objective of the present invention conveniently and clearly.

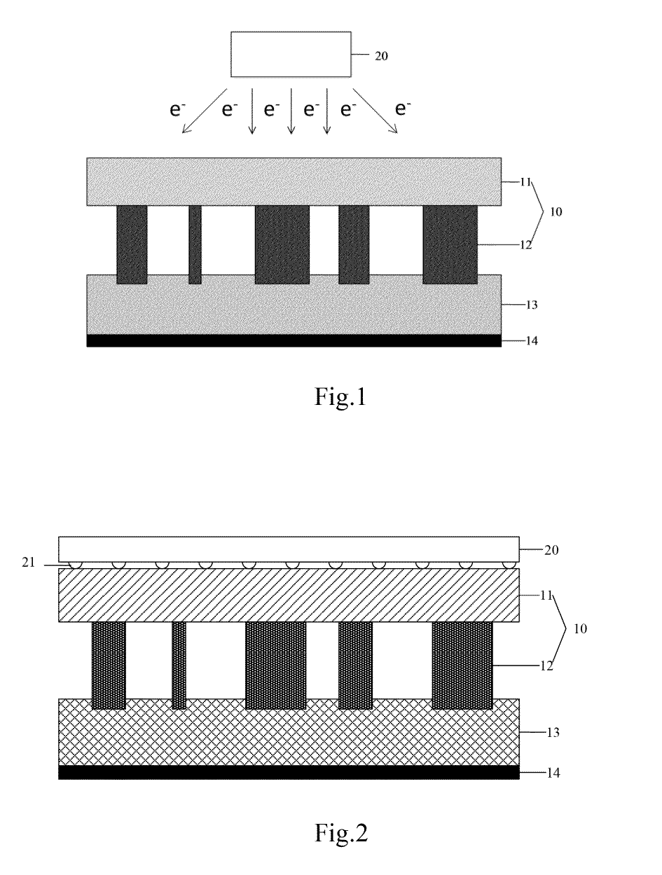

These and other technical features and benefits of the nano-imprint lithography device will be described in further details hereinafter with respect to the embodiment and the accompany drawing FIG. 1.

FIG. 1 is a sectional diagram of the nano-imprint lithography device in a preferred embodiment of the present invention. The device is used to perform a lithography process to a resist 13 on a substrate 14. Wherein, the resist 13 is electron-sensitive. The nano-imprint lithography device comprises an imprint template 10 and an electron source 20. The imprint template 10 comprises a base portion 11 and a pattern portion 12 arranged on the upper surface of the base portion 11.

The imprint template 10 is conductive, and can be made of conductor materials such as metal or doped semiconductors like silicon, silicon germanium. Metal is preferred due to its excellent conductivity. The material of the base portion 11 and that of the pattern portion 12 can be the same or different. in some embodiments, the material of the base portion 11 is the same as that of the pattern portion 12 so that the two portions can be manufactured integrally. Preferably, the material of the base portion 11 is different from that of the pattern portion 12, but both conductive. For example, the base portion 11 is made of silicon while the pattern portion 12 is made of conductor or semiconductor materials other than silicon, which makes it easier for the manufacturing of the imprint template 10 and especially for the control of the etching depth of the pattern portion 12. The manufacturing method of the imprint template 10 is the same as the conventional method, which includes the steps of exposure, development, etching, defect scanning and repairing to form the pattern portion 12 on the base portion 11. The pattern portion 12 is arranged opposed to the surface of the resist 13. The pattern portion 12 has a concave-convex pattern corresponding to the target pattern of the resist to be in contact with the surface of the electron-sensitive resist 13. The shape of the concave-convex pattern is related to the positive or negative property of the resist. When the resist 13 is positive type, the exposure regions of the resist will be dissolved by the developing solution, thus the concave-convex pattern of the pattern portion 12 is the inverse of the target pattern; when the resist 13 is negative type, the non-exposure regions of the resist will be dissolved by the developing solution, thus the concave-convex pattern of the pattern portion 12 is the same as the target pattern.

The shape of the imprint template 10 can be conventional rectangular, or circular or other shapes propitious to manufacturing and quality control. The size of the imprint template 10 can be equal to or less than that of the wafer. By using an imprint template 10 as large as the wafer, the imprint process is required to be performed only once, which saves time and increases efficiency. While by using an imprint template 10 smaller than the wafer, the production cost is low and the imprint accuracy is improved.

The electron source 20 provides electrons for the concave-convex pattern of the pattern portion 12. The electron source 20 can be electron-beam type or contact type. In the embodiment, the electron source is electron-beam type which does not physically contact the template 10. Electrons are ejected from the electron source to the bottom surface of the template 10 and then transferred to the surface of the pattern portion 12. In another embodiment as shown in FIG. 2, the electron source is conventional contact type which covers the bottom surface of the base portion 11. The electron source 20 has multiple electrical contacts 21 on its surface which are in direct physical contact with the bottom surface of the base portion 11. Electrons are introduced into the pattern portion 12 through the electrical contacts 21. Preferably, the electrical contacts 21 are evenly distributed on the surface of the electron source 20 to make the intensity of the electrons in the surface of the pattern portion uniform, so as to obtain the same exposure degree in all the exposure regions of the resist 14.

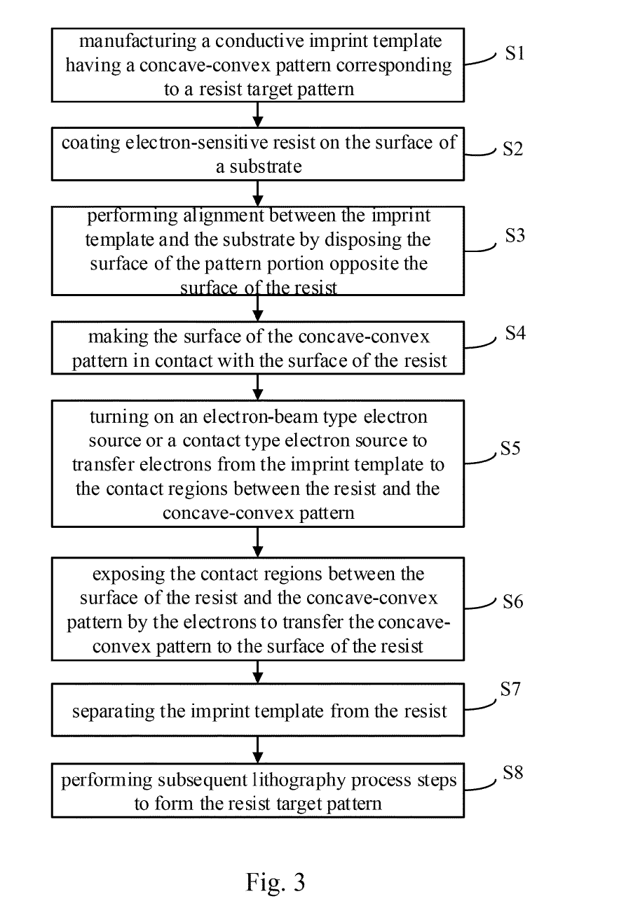

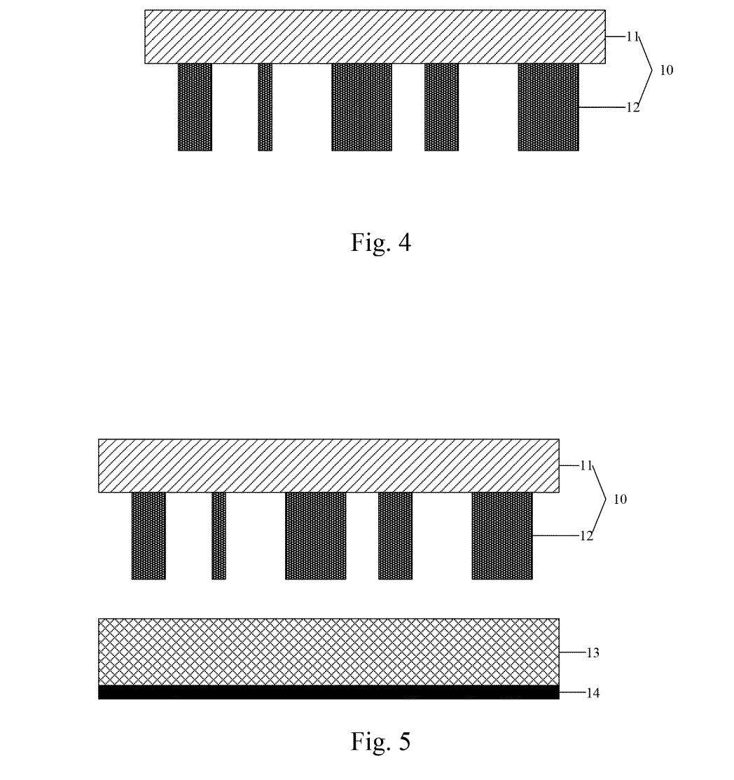

The method for the nano-imprint lithography of the present invention will be described in detail with respect to the FIGS. 3-9. FIG. 3 is a flow chart illustrating the nano-imprint lithography method. FIGS. 4-9 are sectional views illustrating the steps of the nano-imprint lithography method in a preferred embodiment.

Referring to FIG. 3, in the embodiment of the present invention, the method comprises the following steps:

Step S1: manufacturing a conductive imprint template having a concave-convex pattern corresponding to a resist target pattern.

As shown in FIG. 4, an imprint template, especially a pattern portion of the imprint template is required to be manufactured firstly to perform the nano-imprint lithography. In this step, the imprint template is made of conductive materials. The manufacturing method of the imprint template is the same as the conventional method, which involves manufacturing a base portion 11 of the imprint template at first, then depositing the material of the pattern portion and performing steps of exposure, development, etching, defect scanning and repairing, so as to form the pattern portion 12 on the base portion 11. The pattern portion 11 has the concave-convex pattern corresponding to the resist target pattern.

Step S2: coating electron-sensitive resist on the surface of a substrate.

As shown in FIG. 5, the resist 13 is coated on the substrate 14. The resist 13 can be positive or negative type. It is noted that, when the resist 13 is positive type, the exposed part will be dissolved by the developing solution, thus the concave-convex pattern of the pattern portion 12 manufactured in the step S1 is the inverse of the resist target pattern; when the resist 13 is negative type, the non-exposed part will be dissolved by the developing solution, thus the concave-convex pattern of the pattern portion manufactured in the step S1 is the same as the resist target pattern.

Step S3: performing alignment between the imprint template and the substrate by disposing the surface of the pattern portion opposite the surface of the resist.

As shown in FIG. 5, in this step, firstly the pattern portion 12 is disposed opposite the resist 13 on the substrate 14, then the pattern portion 12 and the resist 13 are aligned. Conventional pre-lithography process steps such as baking can also be performed prior to this step.

Furthermore, since the resist is usually hydrophobic, a hydrophilic pretreatment is preferably performed to the surface of the pattern portion 12 prior to this step so that the pattern portion 12 will not be adhered to the resist 13 when it is separated from the resist 13 in the subsequent step S7 and the contamination generated between the imprint template and the resist can be reduced or controlled. Specifically, a hydrophilic thin film is formed on the surface of the pattern portion 12 by soaking the pattern portion 12 in a hydrophilic agent and then baking. However, if the material of the pattern portion itself is hydrophilic such as metals like chromium, aluminum or zinc, the hydrophilic pretreatment process can be omitted. The hydrophilic pretreatment can be performed after the step S1, so that the hydrophilic imprint template can be used repeatedly for lithography processes. It is noted that, considering that the hydrophilicity of the hydrophilic thin film may decrease after a period of time and the hydrophilic effect may not maintain always, it is necessary to perform hydrophilic pretreatment to the imprint template regularly before aligning the imprint template and the photoresist.

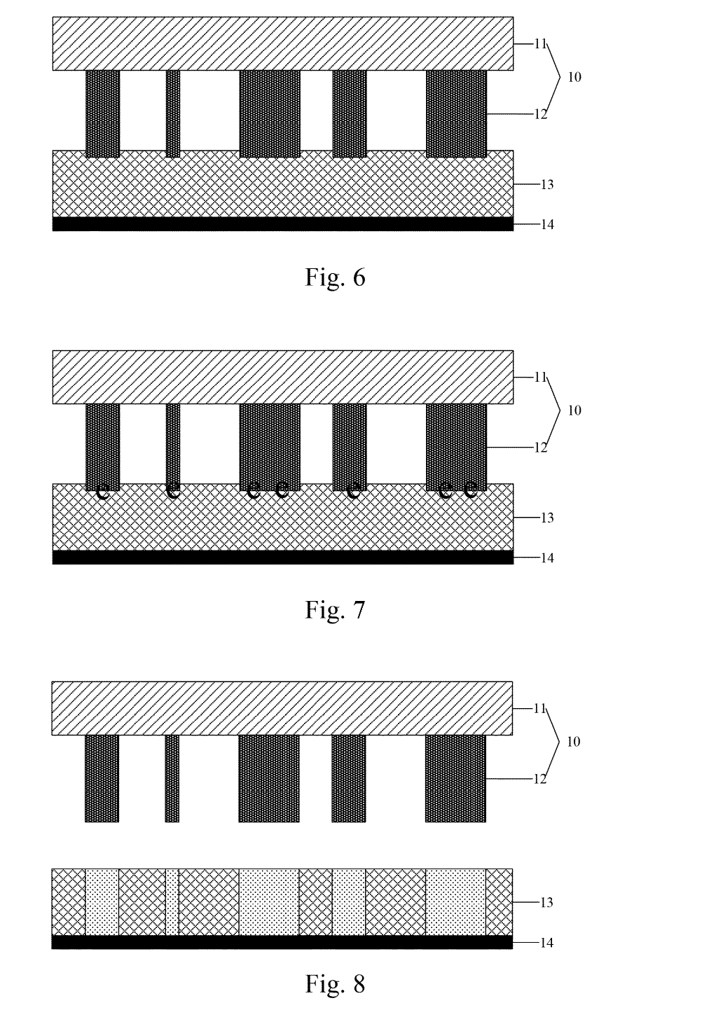

Step S4: making the surface of the concave-convex pattern in contact with the surface of the resist. As shown in FIG. 6, the template 10 is moved vertically to make the pattern portion 12 in contact with the surface of the electron sensitive resist 13 on the substrate 14.

Step S5: turning on an electron-beam type electron source or a contact type electron source to transfer electrons from the imprint template to the contact regions between the resist and the concave-convex pattern.

When the electron-beam type electron source or contact type electron source (not shown) is turned on, the electrons are introduced from the base portion 11 into the pattern portion 12 to make the pattern portion 12 contain electrons e, as shown in FIG. 7. Wherein, the quantity of the ejected electrons and the powering time of the electron source can be controlled according to the process requirements. Since the concave-convex pattern of the pattern portion 12 contacts the surface of the resist 13, the electrons are transferred from the pattern portion 12 to the contact regions between the surface of the resist 13 and the concave-convex pattern of the pattern portion 12.

Step S6: exposing the contact regions between the surface of the resist and the concave-convex pattern by the electrons to transfer the concave-convex pattern to the surface of the resist. Specifically, the contact regions receiving the electrons become filly exposed, which makes the concave-convex pattern of the pattern portion be transferred to the surface of the resist and forms exposure regions and non-exposure regions.

Step S7: separating the imprint template from the resist. As shown in FIG. 8, the pattern portion 12 is separated from the resist 13 on the substrate 14 and the exposure of the resist target pattern is performed. Before separating the imprint template and the resist, the electron source can be powered off firstly by means like shutting down the switch of the electron source 20 physically. Or else, the electrons transfer to the resist can be cut off by departing the template and the resist directly.

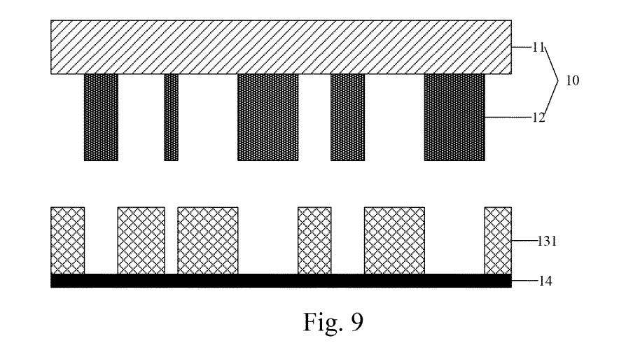

Step S8: performing subsequent lithography process steps to form the resist target pattern. After performing the conventional subsequent lithography process steps such as post-baking and developing (as shown in FIG. 8) to the substrate, the the nano-imprint lithography is completed and the resist target pattern 131 is finally formed as shown in FIG. 9.

Although the present invention has been disclosed as above with respect to the preferred embodiments, they should not be construed as limitations to the present invention. Various modifications and variations can be made by the ordinary skilled in the art without departing the spirit and scope of the present invention. Therefore, the protection scope of the present invention should be defined by the appended claims.

1. A nano-imprint lithography device to perform a lithography process to a substrate coated with an electron-sensitive resist comprising:
a conductive imprint template including a base portion and a pattern portion on the upper surface of the base portion; wherein the pattern portion is disposed opposed to the resist and has a concave-convex pattern corresponding to a target pattern of the resist; and
an electron source providing electrons to the concave-convex pattern of the imprint template;
wherein, when the concave-convex pattern of the template contacts the resist, the electrons transfer from the concave-convex pattern to the resist to make the resist exposed.

2. The nano-imprint lithography device according to claim 1, wherein the material of the base portion and that of the pattern portion are selected from at least one of metal, silicon and silicon germanium.

3. The nano-imprint lithography device according to claim 1, wherein the size of the base portion is equal to or smaller than that of the substrate.

4. The nano-imprint lithography device according to claim 1, wherein the base portion is rectangular or circular.

5. The nano-imprint lithography device according to claim 1, wherein the electron source is electron beam type or contact type.

6. The nano-imprint lithography device according to claim 5, wherein the electron source is a contact type electron source which covers the bottom surface of the base portion and has multiple evenly distributed electrical contacts on its surface to contact the bottom surface of the base portion

7. The nano-imprint lithography device according to claim 1, wherein when the resist is positive type, the concave-convex pattern is the inverse of the target pattern of the resist; when the resist is negative type, the concave-convex pattern is the same as the target pattern of the resist.

8. A nano-imprint lithography method comprising:
step S1: manufacturing a conductive imprint template comprising a base portion and a pattern portion having a concave-convex pattern corresponding to a resist target pattern on the upper surface of the base portion;
step S2: coating electron-sensitive resist on the surface of a substrate;
step S3: performing alignment between the imprint template and the substrate by disposing the surface of the pattern portion opposite the surface of the resist;
step S4: making the surface of the concave-convex pattern in contact with the surface of the resist;
step S5: turning on an electron-beam type electron source or a contact type electron source to transfer electrons from the imprint template to regions where the resist and the concave-convex pattern contact with each other;
step S6: exposing the contact regions between the resist and the concave-convex pattern by the electrons to transfer the concave-convex pattern to the surface of the resist;
step S7: separating the imprint template from the resist;
step S8: performing baking and development to form the resist target pattern.

9. The nano-imprint lithography method according to claim 8, wherein hydrophilic pretreatment is performed to the surface of the pattern portion prior to the step S3.

10. The nano-imprint lithography method according to claim 8, wherein when the resist is positive type, the concave-convex pattern is the inverse of the resist target pattern; when the resist is negative type, the concave-convex pattern is the same as the resist target pattern.
